(19) United States
(12) Patent Application Publication
(10) Pub. No.: US 2004/0113209 A1
(43) Pub. Date: Jun. 17, 2004

(54) MOSFET formed by using salicide process and method of manufacturing the same

(76) Inventors: Mitsuaki Izuha, Yokohama-shi (JP); Toshihiko Iinuma, Yokohama-shi (JP); Kyoichi Suguro, Yokohama-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/660,555

(22) Filed: Sep. 12, 2003

(30) Foreign Application Priority Data
Sep. 13, 2002 (JP) 2002-268970

(51) Int. Cl. H01L 29/76; H01L 29/94; H01L 31/062; H01L 31/113; H01L 31/119

(52) U.S. Cl. 257/388

(57) ABSTRACT

A semiconductor device has a MOSFET. The MOSFET includes source and drain regions, a gate insulating film, a gate electrode, and first, second, and third metal silicide films. The source and drain regions are formed in the major surface region of a semiconductor substrate. The gate insulating film is formed on the channel region between the source and drain regions. The gate electrode is formed on the gate insulating film and includes a poly-Si₁₋ₓGeₓ layer having a Ge/(Si+Ge) composition ratio x (0<x<0.2). The first metal silicide film is formed on the gate electrode and made of NiSi_{1-y}Ge_{y}. The second and third metal silicide films are formed on the source and drain regions, respectively, and made of NiSi.

### CROSS-REFERENCE TO RELATED APPLICATIONS

This application is based upon and claims the benefit of priority from the prior Japanese Patent Application No. 2002-268970, filed Sep. 13, 2002, the entire contents of which are incorporated herein by reference.

### BACKGROUND OF THE INVENTION

1. Field of the Invention

The present invention relates to a semiconductor device and a method of manufacturing the same and, more particularly, to a transistor (MOSFET) formed by using a salicide process and a method of manufacturing the same. The present invention is applied to the contact portion between a gate electrode and source and drain regions and their lead electrodes.

2. Description of the Related Art

In recent years, introduction of poly-SiGe as a gate electrode material in a MOSFET has been examined to suppress depletion. CoSi₂ that has been mainly used as a contact material at present forms Co(Si_{1-y}Ge_{y}) at first cold RTA (about 400° C.). At second hot RTA (about 700° C.), however, CoSi₂ emits Ge to form an SiGe layer as a Ge-rich island and CoSi₂. As a result, the sheet resistance considerably increases (e.g., Z. Wang, D. B. Aldrich, Y. L. Chen, D. E. Sayers and R. J. Nemanich, Thin Solid Films, Vol. 270 (1995), pp. 555-560). For this reason, when poly-SiGe is used for a gate electrode, a poly-Si cap layer must be inserted to the interface to CoSi₂, as is known.

Additionally, in MOSFETs after a generation with a gate length of 50 nm, NiSi has been examined as a contact material to which a salicide process is to be applied. A disadvantage of NiSi is that the heat resistance is lower than that of TiSi₂ or CoSi₂ in conventional devices. However, when NiSi is used as a contact material on poly-SiGe, no serious mismatch with poly-SiGe occurs, unlike CoSi₂ described above. To improve the heat resistance, use of an Siₓ(Ge_{y}C_{1-y})₁₋ₓ compound layer 28a on the lower side of a lead electrode 28 has been proposed (e.g., Jpn. Pat. Appln. KOKAI Publication No. 11-214680).

In the invention described in this prior art, interface mismatch to a gate electrode or source and drain diffusion layers is reduced. Accordingly, any change in Schottky barrier after post-annealing and accompanying change in contact resistance are suppressed.

Independently of the problem of heat resistance, a problem that the sheet resistance of Ni silicide increases after annealing at a high temperature is known. The cause may be formation (phase transition) or aggregation of NiSi₂ having a high resistivity.

As a measure against this problem, introduction of a Co intermediate layer to the Ni/Si or Ni/SiGe interface has been reported (e.g., J- S. Maa, D. J. Tweet, Y. Ono, L. Stecker and S. T. Hsu, Mat. Res. Soc. Symp. Proc. Vol. 670, K6.9.1 (2001)). However, this poses new problems for integration and, for example, increases the number of manufacturing processes.

### BRIEF SUMMARY OF THE INVENTION

According to an aspect of the present invention, there is provided a semiconductor device having a MOSFET, the MOSFET comprising source and drain regions formed in a major surface region of a semiconductor substrate, a gate insulating film formed on a channel region between the source and drain regions, a gate electrode which is formed on the gate insulating film and includes a poly-Si₁₋ₓGeₓ layer having a Ge/(Si+Ge) composition ratio x (0<x<0.2), a first metal silicide film which is formed on the gate electrode and essentially consists of NiSi_{1-y}Ge_{y}, and second and third metal silicide films which are formed on the source and drain regions, respectively, and essentially consist of NiSi.

According to another aspect of the present invention, there is provided a method of manufacturing a semiconductor device, comprising forming a gate insulating film on a semiconductor substrate, forming a gate electrode including a poly-Si₁₋ₓGeₓ layer which has a Ge/(Si+Ge) composition ratio x (0<x<0.2) on the gate insulating film, doping an impurity into a major surface region of the semiconductor substrate to form source and drain regions, forming an Ni film on the gate electrode and the source and drain regions, and performing annealing to change the Ni film on the gate electrode into an NiSi_{1-y}Ge_{y} film and the Ni films on the source and drain regions into NiSi films.

### BRIEF DESCRIPTION OF THE SEVERAL VIEWS OF THE DRAWING

FIG. 1 is a sectional view showing the sectional structure of a MOSFET so as to explain a semiconductor device according to an embodiment of the present invention;

FIG. 2 is a sectional view showing the first step in manufacturing the MOSFET shown in FIG. 1 so as to explain the method of manufacturing the semiconductor device according to the embodiment of the present invention;

FIG. 3 is a sectional view showing the second step in manufacturing the MOSFET shown in FIG. 1, following FIG. 2, so as to explain the method of manufacturing the semiconductor device according to the embodiment of the present invention;

FIG. 4 is a sectional view showing the third step in manufacturing the MOSFET shown in FIG. 1, following FIG. 3, so as to explain the method of manufacturing the semiconductor device according to the embodiment of the present invention;

FIG. 5 is a sectional view showing the fourth step in manufacturing the MOSFET shown in FIG. 1, following FIG. 4, so as to explain the method of manufacturing the semiconductor device according to the embodiment of the present invention;

FIG. 6 is a sectional view showing the fifth step in manufacturing the MOSFET shown in FIG. 1, following FIG. 5, so as to explain the method of manufacturing the semiconductor device according to the embodiment of the present invention;

FIG. 7 is a graph showing the relationship between the Ge concentration and the sheet resistance of a metal silicide film formed on a boron-doped gate electrode of a P-channel MOSFET;

FIG. 8A is a schematic view for explaining a double implantation portion of p- and n-impurities in an actual device;

FIG. 8B is a schematic view for explaining an undoped portion due to, e.g., PEP misalignment in an actual device; and

FIG. 9 is a graph showing the relationship between the Ge concentration and the sheet resistance of a metal silicide film formed on a gate electrode having an undoped portion.

### DETAILED DESCRIPTION OF THE INVENTION

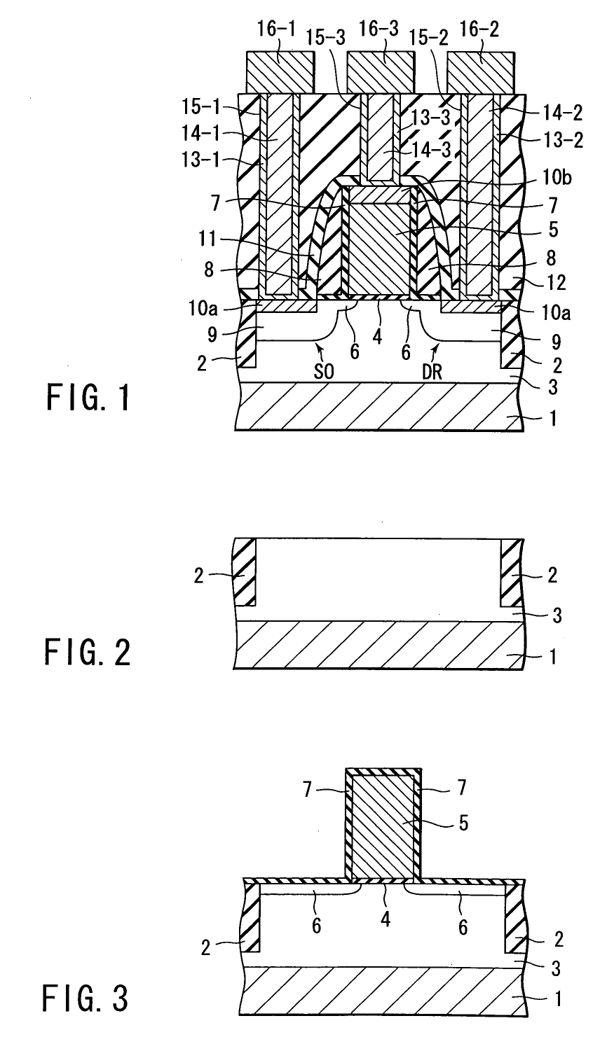

FIG. 1 is a sectional view showing a MOSFET so as to explain a semiconductor device according to an embodiment of the present invention.

A substrate 1 is an n- or p-type silicon substrate. An element isolation structure 2 is formed on the major surface of the substrate 1 by, e.g., a burying element isolation method. A p- or n-type well region 3 is formed in the active element region of the substrate 1, which is defined by the element isolation structure 2. Source and drain regions SO and DR that sandwich a channel region are formed in the well region 3. The source and drain regions SO and DR have structures with source and drain extensions. The source and drain regions SO and DR are formed from heavily doped impurity diffusion regions 9 and lightly doped impurity diffusion regions 6 formed near the channel region in the regions 9. A metal silicide film (NiSi) 10a is formed on each heavily doped impurity diffusion region 9 by a salicide process.

A gate insulating film 4 is formed on the channel region between the source and drain regions SO and DR. The gate insulating film 4 may be made of a silicon oxide film. However, the material preferably includes a silicon nitride film. A gate electrode 5 is formed on the gate insulating film 4. The gate electrode 5 has a single-layered structure of a poly-Si_{0.88}Ge_{0.12} layer or a two-layered structure having a poly-Si_{0.88}Ge_{0.12} layer formed on a poly-Si layer. The poly-Si_{0.88}Ge_{0.12} layer is preferably formed from poly-Si₁₋ₓGeₓ with a Ge/(Si+Ge) composition x (0<x<0.2 and, more preferably, 0.04≦x≦0.16). In this example, poly-Si_{0.088}Ge_{0.12} is used.

On the gate electrode 5, a metal silicide film (NiSi_{1-y}Ge_{y} (y is almost equal to x); e.g., NiSi_{0.88}Ge_{0.12}) 10b is formed by the salicide process. Silicon oxide films serving as post-oxide films 7 and sidewall insulating films 8 are formed on the sidewall portions of the gate electrode 5. The sidewall insulating films 8 are structures necessary in the manufacturing process for forming the source and drain regions SO and DR described above. The sidewall insulating film 8 is formed from, e.g., a silicon nitride film and a silicon oxide film. Offset spacers may be formed on the sidewall portions of the gate electrode 5.

An interlayer dielectric film including, e.g., a silicon nitride film 11 and a silicon oxide film 12 is formed on the MOSFET. Contact holes 15-1, 15-2, and 15-3 are formed in the interlayer dielectric film at positions corresponding to the source and drain regions SO and DR (metal silicide films 10a) and a position corresponding to the gate electrode 5 (metal silicide film 10b). Tungsten (W) plugs 14-1, 14-2, and 14-3 are buried in the contact holes 15-1, 15-2, and 15-3 via barrier metal layers 13-1, 13-2, and 13-3 each made of a TiN film or a multilayered structure of TiN and Ti, respectively.

Lead electrodes such as a source interconnection 16-1, drain interconnection 16-2, and gate inter-connection 16-3 are formed on the interlayer dielectric film and electrically connected to the W plugs 14-1, 14-2, and 14-3.

As described in this embodiment, when a poly-Si₁₋ₓGeₓ layer having the composition ratio x (0<x<0.2 and, more preferably, 0.04≦x≦0.16) is used as the gate electrode material of the MOSFET, any increase in sheet resistance of the metal silicide film 10b on the gate electrode 5 can be suppressed. Accordingly, the parasitic resistance of the transistor can be reduced, and the switching speed can be increased.

As described above, as the gate electrode 5, a single-layered structure of poly-Si₁₋ₓGeₓ or a two-layered structure of poly-Si₁₋ₓGeₓ/poly-Si (poly-Si is formed on the side of the interface to the gate insulating film) is used. When the poly-Si₁₋ₓGeₓ layer is thin, Ni readily passes through Si₁₋ₓGeₓ and preferentially reacts with Si. For Ni, the thickness of the underlying Si₁₋ₓGeₓ layer, which is consumed by the reaction, is almost the same as the thickness of the Ni film before the reaction. In consideration of a margin by morphology roughness on the NiSi_{1-y}Ge/Si₁₋ₓGeₓ interface, the Si₁₋ₓGeₓ layer preferably has a thickness at least about twice that of the Ni film before reaction.

According to experiments conducted by the present inventors, when the Si₁₋ₓGeₓ layer was thin, the sheet resistance increased. Cross-section TEM observation revealed that Ni silicide passed through Si₁₋ₓGeₓ, reacted with Si, and aggregated. This is supposedly because an Ni—Ge bond is more stable than an Ni—Si bond in terms of energy, and NiSi is formed more easily than NiSi_{1-y}Ge_{y}.

According to the above arrangement, when NiSi is used as a contact material, the switching speed of the transistor can be increased while avoiding any problem of heat resistance, including an increase in interface resistance to the source and drain regions or gate electrode due to the post-annealing at a high temperature and an increase in sheet resistance.

A method of manufacturing the MOSFET shown in FIG. 1 will be described next. FIGS. 2 to 6 are sectional views showing steps in manufacturing the MOSFET shown in FIG. 1.

As shown in FIG. 2, the element isolation structure 2 having a depth of about 300 nm is formed in the p- or n-type silicon substrate 1 by, e.g., a burying element isolation method. Thermal oxidation is performed to form a silicon oxide film having a thickness of about 10 nm on the active element region. Impurity ions are implanted into the substrate 1 via the oxide film to form the well region 3 and channel stopper. As typical ion implantation conditions at this time, when, e.g., a p-well region is to be formed, boron (B) is ion-implanted at an acceleration energy of 260 KeV and a dose of 2.0×10¹³ cm⁻². For an n-well region, phosphorus (P) is ion-implanted at an acceleration energy of 500 KeV and a dose of 2.5×10¹³ cm⁻².

As shown in FIG. 3, the gate insulating film 4 (Si₃N₄, SiO₂+Si₃N₄, or SiOₓN_{y}+Si₃N₄,) having a thickness of 1 to 5 nm is formed on the active element region. For example, a poly-Si_{0.88}Ge_{0.12} layer is formed (or a poly-Si layer and a poly-Si_{0.88}Ge_{0.12} layer are sequentially formed) on the gate insulating film 4 and patterned to form the gate electrode 5. A post-oxidation process is executed to form the post-oxide films 7 on the major surface of the substrate 1 and the upper and side surfaces of the gate electrode 5. Offset spacers (not shown) are formed on the sidewalls of the gate electrode 5, as needed. Then, ions are implanted into the major surface region of the substrate 1 using the gate electrode 5 as a mask to form the source and drain extensions (lightly doped impurity diffusion regions 6). As typical ion implantation conditions for extension formation, when an n-type region is to be formed, arsenic (As) is ion-implanted at an acceleration energy of 10 KeV and a dose of 5×10¹⁴ cm⁻². For a p-type region, BF₂ is ion-implanted at an acceleration energy of 7 KeV and a dose of 5×10¹⁴ cm⁻².

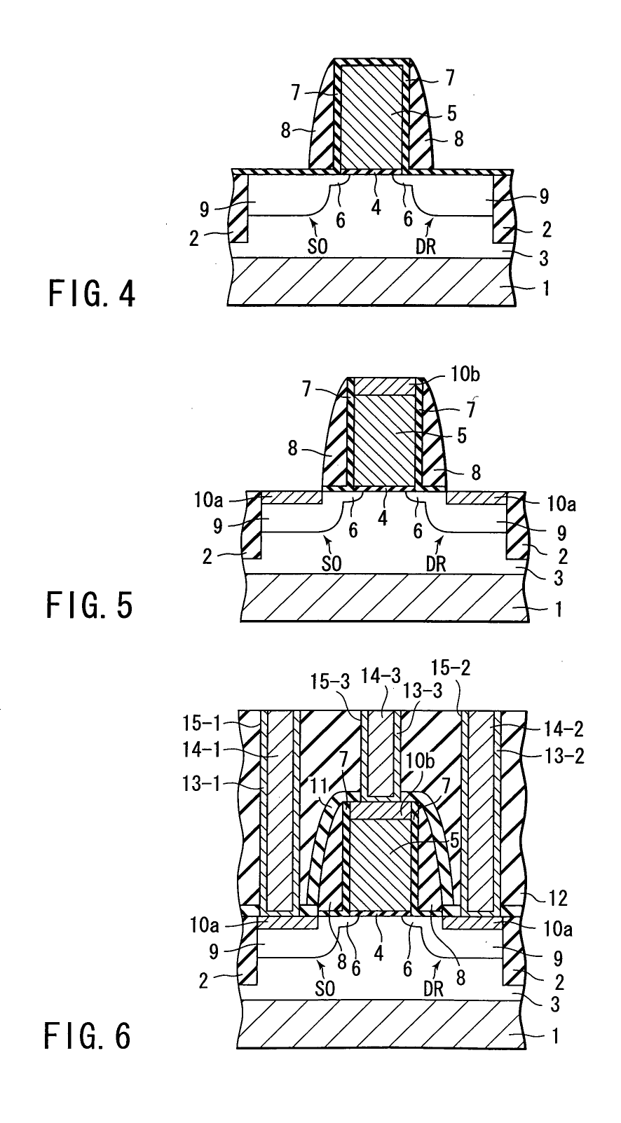

As shown in FIG. 4, activation RTA (Rapid Thermal Annealing) is executed at about 800° C. After that, the sidewall insulating films 8 each including a silicon nitride film and a silicon oxide film are formed by techniques such as CVD and anisotropic etching. Ions are implanted into the major surface region of the substrate 1 using the gate electrode 5 and sidewall insulating films 8 as a mask to form deep junctions (heavily doped impurity diffusion regions 9). As typical ion implantation conditions for formation of the deep junctions, when an n-type region is to be formed, As is ion-implanted at an acceleration energy of 50 KeV and a dose of 7×10¹⁵ cm⁻². For a p-type region, B is ion-implanted at an acceleration energy of 5 KeV and a dose of 4×10¹⁴ cm⁻². After that, activation RTA is executed at about 1,000° C. to activate the dopant in the impurity diffusion layers serving as the source and drain regions SO and DR.

When the post-oxide films 7 remain on the source and drain regions So and DR and gate electrode 5, the post-oxide films 7 are removed by a chemical process. Then, an Ni film is formed on the entire surface using sputtering (or CVD). The thickness of the Ni film is about 10 to 15 nm. The thicker the Ni film becomes, the more the increase in sheet resistance due to aggregation can be suppressed. Accordingly, however, the junction leakage level increases. Hence, the thickness is preferably about 10 to 15 nm. Next, RTA is executed at 500° C. to change the Ni films on the source and drain regions SO and DR and the Ni film on the gate electrode 5 into the metal silicide films (NiSi) 10a and the metal silicide film (NiSi_{0.88}Ge_{0.12}) 10b, respectively. When the RTA temperature was as low as 450° C. or less, the reaction did not sufficiently progress, and Ni₂Si_{0.88}Ge_{0.12} remained on the surface of NiSi_{0.88}Ge_{0.12}. When a chemical process using HCl and H₂O₂ or O₃ was executed in the state wherein Ni₂Si_{0.88}Ge_{0.12} remained, extra Ni reacted with the chemical solution so that film peeling took place. When the peeled portion was analyzed, Ni at that portion disappeared, and instead, an SiO₂ layer was observed. When an unreacted metal (Ni film) is removed by selective etching, a structure shown in FIG. 5 is obtained.

As shown in FIG. 6, the silicon nitride film 11 and silicon oxide film 12 are deposited as interlayer dielectric films. Then, CMP is executed to planarize the surface. RIE is executed to form the contact holes 15-1, 15-2, and 15-3 to be used to form the lead electrodes of the source and drain regions SO and DR and gate electrode 5. After a Ti film is formed by CVD, the resultant structure is nitrided by annealing in an N₂ atmosphere (or NH₃ atmosphere or FG (N₂ containing 3% H₂) atmosphere) at about 550° C. for 60 min, thereby forming the barrier metal layers 13-1, 13-2, and 13-3 each at least partially having a TiN film. The temperature of this annealing is the highest after formation of the metal silicide films 10a and 10b. In addition, the tungsten (W) plugs 14-1, 14-2, and 14-3 are buried by CVD. CMP is executed to planarize the surface of the interlayer dielectric film.

After a metal such as aluminum is deposited and patterned to form the lead electrodes such as the source interconnection 16-1, drain interconnection 16-2, and gate interconnection 16-3, thereby completing the MOSFET shown in FIG. 1.

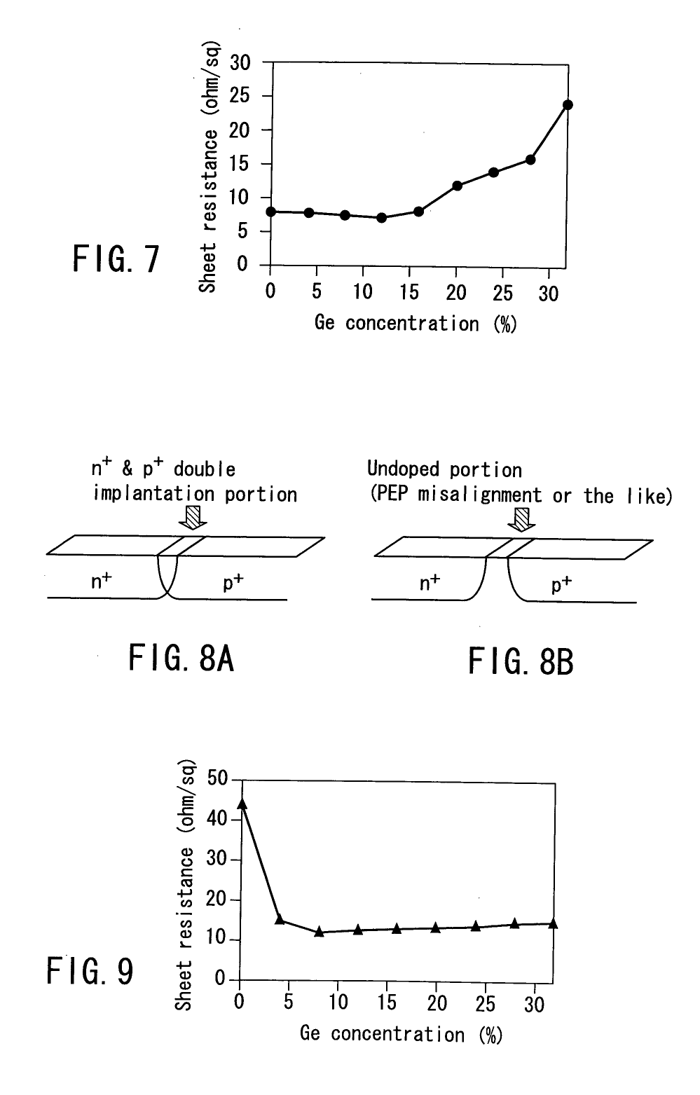

In this embodiment, the Ge/(Si+Ge) composition ratio of poly-Si₁₋ₓGeₓ serving as the gate electrode material is important FIG. 7 shows the relationship between the Ge concentration of the metal silicide (NiSi_{1-y}Ge_{y}) film formed on the boron (B)-doped gate electrode (poly-Si₁₋ₓGeₓ) of a P-channel MOSFET and the sheet resistance of the metal silicide on the gate electrode. In other words, FIG. 7 shows the dependence of the sheet resistance on the Ge/(Si+Ge) composition ratio. As is apparent from FIG. 7, the sheet resistance rarely changes when the Ge/(Si+Ge) composition ratio range is 0 to 0.16 (0% to 16%). However, the sheet resistance abruptly increases when the Ge/(Si+Ge) composition ratio exceeds 0.2 (20%).

The same tendency as described above was observed even in the metal silicide (NiSi_{1-y}Ge_{y}) film on the phosphorus (P)- or arsenic (As)-doped gate electrode (poly-Si₁₋ₓGeₓ) of an N-channel MOSFET.

An actual device has a double implantation portion of p- and n-impurities, as shown in FIG. 8A, or an undoped portion due to PEP misalignment, as shown in FIG. 8B.

FIG. 9 shows the relationship between the Ge concentration and the sheet resistance of a metal silicide film (NiSi_{1-y}Ge_{y}) formed on a gate electrode (poly-Si₁₋ₓGeₓ) having an undoped portion corresponding to FIG. 8B. That is, FIG. 9 shows the dependence of the sheet resistance on the Ge/(Si+Ge) composition ratio. In this case, a quite different tendency from that in FIG. 7 is obtained. The sheet resistance increased in a gate electrode (poly-Si) which corresponded to a Ge/(Si+Ge) composition ratio of 0. Cross-section SEM observation and EDX analysis were executed as physical analysis. In the NiSi film on the gate electrode including the poly-Si layer, aggregation with phase transition to the NiSi₂ film was observed. On the other hand, no phase transition was observed in the NiSi_{0.88}Ge_{0.12} film on the gate electrode including the poly-Si_{0.88}Ge_{0.12} layer used in this embodiment.

The crystal particle sizes of poly-Si and Si₁₋ₓGeₓ shown in FIG. 9 were almost the same. As the tendency of heat resistance, the larger the crystal particle size becomes, the more easily aggregation progresses, and the higher the sheet resistance becomes. When the crystal particle size is small, aggregation hardly progresses. However, phase transition to NiSi₂ readily occurs, and the sheet resistance increases accordingly.

As described in the above embodiment, when a gate electrode material including a poly-Si₁₋ₓGeₓ layer having the Ge/(Si+Ge) composition ratio x (0<x<0.2 and, more preferably, 0.04≦x≦0.16) is selected, any increase in sheet resistance in both a gate electrode including a poly-Si₁₋ₓGeₓ layer doped with an impurity and a non-doped gate electrode can be suppressed.

Hence, in a MOSFET for which annealing is executed after formation of metal silicide films, any increase in sheet resistance of the metal silicide on the gate electrode can be suppressed. When the increase in sheet resistance is suppressed, the parasitic resistance of the transistor can also be reduced, and the switching speed can be increased. In addition, any increase in sheet resistance at various pattern portions such as an undoped portion due to PEP misalignment can also be suppressed. Hence, the manufacturing yield and reliability can be increased.

In the above-described embodiment, the combination of Ni and SiGe has been described in association with a gate electrode. Independently, an attempt to increase the junction depth by epitaxially growing Si or SiGe on an Si substrate in source and drain regions has been examined. Even in this case, when the Ge concentration is set to be low as in the gate electrode, as described above, aggregation of Ni silicide and phase transition to NiSi₂ can be suppressed.

As described above, according to one aspect of this invention, a semiconductor device in which when NiSi is used as a contact material, the switching speed of the transistor can be increased while avoiding any problem of heat resistance, including an increase in sheet resistance of a gate electrode due to the post-annealing at a high temperature, can be obtained.

In addition, a semiconductor device manufacturing method which can increase the manufacturing yield and reliability can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device having a MOSFET, the MOSFET comprising:
source and drain regions formed in a major surface region of a semiconductor substrate;
a gate insulating film formed on a channel region between the source and drain regions;
a gate electrode which is formed on the gate insulating film and includes a poly-Si₁₋ₓGeₓ layer having a Ge/(Si+Ge) composition ratio x (0<x<0.2);
a first metal silicide film which is formed on the gate electrode and essentially consists of NiSi_{1-y}Ge_{y}; and
second and third metal silicide films which are formed on the source and drain regions, respectively, and essentially consist of NiSi.

2. The device according to claim 1, wherein the Ge/(Si+Ge) composition ratio more preferably falls within a range of 0.04≦x≦0.16.

3. The device according to claim 1, further comprising an interlayer dielectric film which is formed on the MOSFET, a first metal plug which is formed in a first contact hole formed in the interlayer dielectric film on the gate electrode, a first barrier metal layer which is inserted between the first metal plug and the first metal silicide film, second and third metal plugs which are formed in second and third contact holes formed in the interlayer dielectric film on the source and drain regions, respectively, and second and third barrier metal layers which are inserted between the second and third metal plugs and the second metal silicide film.

4. The device according to claim 3, wherein the first to third metal plugs essentially consist of tungsten, and the first to third barrier metal layers contain TiN.

5. The device according to claim 1, wherein a thickness of the poly-Si₁₋ₓGeₓ layer in the gate electrode is at least twice that of the first metal silicide film.

6. The device according to claim 1, which further comprises a well region which is formed in the semiconductor substrate, and in which the source and drain regions are formed in the well region, the source and drain regions have structures with source and drain extensions, and first and second heavily doped impurity diffusion regions and third and fourth lightly doped impurity diffusion regions formed near the channel region in the first and second impurity diffusion regions.

7. A method of manufacturing a semiconductor device, comprising:
forming a gate insulating film on a semiconductor substrate;
forming a gate electrode including a poly-Si₁₋ₓGeₓ layer which has a Ge/(Si+Ge) composition ratio x (0<x<0.2) on the gate insulating film;
doping an impurity into a major surface region of the semiconductor substrate to form source and drain regions;
forming an Ni film on the gate electrode and the source and drain regions; and
performing annealing to change the Ni film on the gate electrode into an NiSi_{1-y}Ge_{y} film and the Ni films on the source and drain regions into NiSi films.

8. The method according to claim 7, wherein the Ge/(Si+Ge) composition ratio more preferably falls within a range of 0.04≦x≦0.16.

9. The method according to claim 7, further comprising
forming an interlayer dielectric film on the NiSi_{1-y}Ge_{y} and NiSi films and forming first to third contact holes in the interlayer dielectric film at positions corresponding to the gate electrode and source and drain regions,
forming first to third barrier metal layers in the first to third contact holes, and
burying first to third metal plugs on the first to third barrier metal layers in the first to third contact holes.

10. The method according to claim 7, further comprising, before formation of the gate insulating film,
forming an element isolation structure on the major surface of the semiconductor substrate, and
forming a well region in an active element region defined by the element isolation structure.

11. The method according to claim 7, wherein formation of the source and drain regions includes
ion-implanting an impurity into the major surface region of the semiconductor substrate using the gate electrode as a mask to form first and second lightly doped impurity diffusion regions,
forming sidewall insulating films on sidewall portions of the gate electrode, and
ion-implanting an impurity into the major surface region of the semiconductor substrate using the gate electrode and the sidewall insulating films as a mask to form third and fourth heavily doped impurity diffusion regions.

12. The method according to claim 9, wherein formation of the interlayer dielectric film includes
depositing a silicon nitride film on the major surface of the semiconductor substrate and upper and side surfaces of the gate electrode, and
depositing a silicon oxide film on the silicon nitride film.

13. The method according to claim 9, wherein formation of the first to third barrier metal layers includes
forming a Ti film on the interlayer dielectric film and in the first to third contact holes, and
nitriding the Ti film to convert at least part of the Ti film into a TiN film.

14. The method according to claim 9, wherein burying of the first and third metal plugs includes
forming a tungsten layer on the lightly doped impurity diffusion regions and in the first to third contact holes by CVD, and
executing CMP to planarize the surface and leaving the tungsten layer in the first to third contact holes to form the first to third metal plugs.
